(19) United States
(12) Patent Application Publication
(10) Pub. No.: US 2006/0237737 A1
(43) Pub. Date: Oct. 26, 2006

(54) Light emitting diode and backlight module having light emitting diode

(75) Inventor: I-Chang Lee, Tainan City (TW)

Correspondence Address: LADAS & PARRY, 26 WEST 61ST STREET, NEW YORK, NY, 10023, US

(73) Assignee: CHI LIN TECHNOLOGY CO. LTD.

(21) Appl. No.: 11/471,939

(22) Filed: Jun. 21, 2006

Related U.S. Application Data
(62) Division of application No. 11/018,157, filed on Dec. 21, 2004.

(30) Foreign Application Priority Data
Jul. 16, 2004 (TW) 093121418

(51) Int. Cl. H01L 33/00

(52) U.S. Cl. 257/98

(57) ABSTRACT

The present invention relates to a light emitting diode comprising a blue die and a fluorescent material layer. The blue die is used for generating blue light when being activated. The fluorescent material layer is used for generating yellow light when being activated. The light emitting diode further comprises a red die that is used for generating red light when being activated, so as to increase the red color component of the output light of the light emitting diode. The present invention also relates to a backlight module having light emitting diode, which has a well-balanced color when being used for a light source of a liquid crystal display or a liquid crystal display television.

### BACKGROUND OF THE INVENTION

1. Field of the Invention

The present invention relates to a light emitting diode and backlight module having light emitting diode, particularly to a light emitting diode and backlight module that has an output light of well-balanced color.

2. Description of the Related Art

FIG. 1 shows a perspective view of a conventional backlight module. The conventional backlight module 1 comprises a plurality of lamps 11, a diffusion plate 12, a reflective plate 13 and a housing 14. The backlight module 1 is disposed under a liquid crystal plate in a liquid crystal display device (not shown in the figure). The lamps 11 are used for providing light beams. The reflective plate 13 is disposed under the lamps 11 and is used for reflecting light beams generated by the lamps 11 to the diffusion plate 12. The diffusion plate 12 is disposed above the lamps 11 and is used for diffusing the light beams generated by the lamps 11 and reflected by the reflective plate 13 so that the liquid crystal plate has an even distribution of light beams. The housing 14 is a square frame, which accommodates the lamps 11, the diffusion plate 12, and the reflective plate 13. The lamps 11 of the conventional backlight module 1 are cold cathode fluorescent lamps (CCFL), which has a shortcoming of deficient intensity in the green region of the visible light spectrum. When the conventional backlight module 1 is applied in a liquid crystal display device, the green color is weakly displayed on the liquid crystal display device, which causes poor color rendition. Therefore, when being selected to be the light source of the conventional backlight module 1, the cold cathode fluorescent lamps are gradually replaced by light emitting diodes.

FIG. 2 is a diagram of a conventional light emitting diode. The conventional light emitting diode 2 comprises a blue die 21, a reflector cup lead frame 22, two leads 23 and 24, a fluorescent material layer 25 and an encapsulant 26. The blue die 21 is a Gallium Nitride (GaN) die and is used for generating blue light when being activated. The reflector cup lead frame 22 is used for receiving the blue die 21 and the fluorescent material layer 25. The blue die 21 is electrically coupled to the leads 23 and 24 that are electrically connected to an outer power source, which provides electrical power to the blue die 21. The fluorescent material layer 25 comprises Yttrium Aluminum Garnet (YAG) phosphor and covers the blue die 21. The fluorescent material layer 25 is used for generating yellow light when being activated. The blue die 21 and the fluorescent material layer 25 are encapsulated by the encapsulant 26 which is a transparent epoxy. The output light of the conventional light emitting diode 2 is white light and has a shortcoming of deficient intensity in the red region of the visible light spectrum, which causes unbalanced color distribution.

Referring to FIG. 3, a spectral distribution of the white light generated by the conventional light emitting diode 2 is shown, wherein the blue die 21 is applied by a direct current of 400 mA. The spectral distribution of the conventional light emitting diode 2 includes two peaks 31 and 32, wherein the peak 31 is primarily caused by the blue die 21, and the peak 32 is primarily caused by the fluorescent material layer 25. As shown in the figure, the spectral distribution of the conventional light emitting diode 2 is deficient in the red region of the visible light spectrum (the range of 610 to 680 nm). When being used as a light source of a backlight for a liquid crystal display device, the red deficiency in the output light causes poor color rendition of the liquid crystal display device.

In order to overcome the above-mentioned shortcoming, U.S. Pat. No. 6,351,069 B1 discloses a red-deficiency-compensating phosphor LED characterized in that a supplementary phosphor is added to a fluorescent material layer thereof so as to increase the red color component of its output light and compensate the red deficiency in the output light. However, such way will cause loss in brightness of the light emitting diode. Therefore, when being used as a light source of backlight module, it will reduce the brightness of the display device.

Consequently, there is an existing need for a novel and improved light emitting diode and backlight module to solve the above-mentioned problem.

### SUMMARY OF THE INVENTION

One objective of the present invention is to improve the color saturation of a liquid crystal display television (LCD TV) or a liquid crystal display device.

Another objective of the present invention is to provide a light emitting diode that has a blue die and a red die so as to compensate the red deficiency in the output light. When the light emitting diode is used as a light source of a backlight module, it can increase the color saturation.

Another objective of the present invention is to provide a backlight module that has cold cathode fluorescent lamps and green light emitting diodes so as to compensate the green deficiency in the output light. When the backlight module is used as a light source of a liquid crystal display television or a liquid crystal display device, it can increase the color saturation.

Another objective of the present invention is to provide a backlight module that has white light emitting diodes and red light emitting diodes so as to compensate the red deficiency in the output light. When the backlight module is used as a light source of a liquid crystal display television or a liquid crystal display device, it can increase the color saturation.

### BRIEF DESCRIPTION OF THE DRAWINGS

FIG. 1 shows a perspective view of a conventional backlight module;

FIG. 2 is a diagram of a conventional light emitting diode;

FIG. 3 shows a spectral distribution of the white light generated by the conventional light emitting diode of FIG. 2;

FIG. 4 shows a perspective view of a backlight module according to the present invention, wherein the light emitting diodes adapted in the backlight module are conventional;

FIG. 5 is a diagram of a light emitting diode according to the present invention;

FIG. 6 shows a spectral distribution of the white light generated by the light emitting diode of FIG. 5;

FIG. 7 shows a perspective view of a backlight module according to the present invention, wherein the light emitting diodes of FIG. 5 are adapted in the backlight module; and

FIG. 8 shows a perspective view of another type of backlight module according to the present invention.

### DETAILED DESCRIPTION OF THE INVENTION

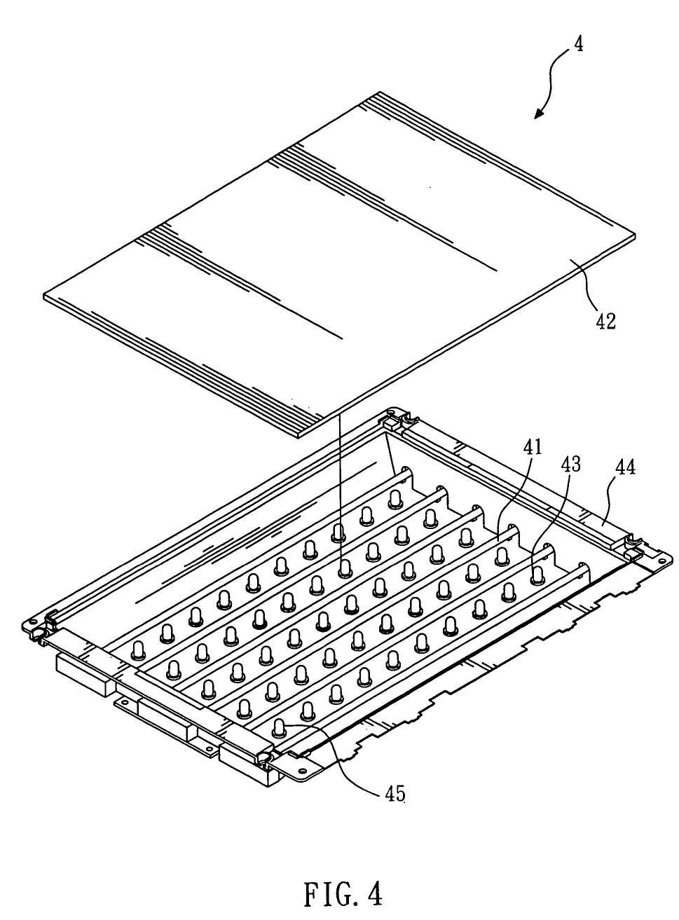

FIG. 4 shows a perspective view of a backlight module according to the present invention, wherein the light emitting diodes adapted in the backlight module are conventional. The backlight module 4 comprises a plurality of lamps 41, a diffusion plate 42, a reflective plate 43, a housing 44 and a plurality of green light emitting diodes 45.

The backlight module 4 is disposed under a liquid crystal plate in a liquid crystal display device (not shown in the figure). The lamps 41 are cold cathode fluorescent lamps and are used for providing light beams. The reflective plate 43 is disposed under the lamps 41 and is used for reflecting light beams generated by the lamps 41 to the diffusion plate 42. The diffusion plate 42 is disposed above the lamps 41 and is used for diffusing the light beams generated by the lamps 41 and the green light emitting diodes 45 and reflected by the reflective plate 43 so that the liquid crystal plate has an even distribution of light beams. The housing 44 is a square frame, which accommodates the lamps 41, the diffusion plate 42, and the reflective plate 43. The green light emitting diodes 45 are conventional green light emitting diodes and are used for compensating green deficiency in the output light of the lamps 41. As a result, when the backlight module 4 is used as a light source of a liquid crystal display television or a liquid crystal display device, it can increase the color saturation of the liquid crystal display television or the liquid crystal display device.

In this embodiment, each of the green light emitting diodes 45 is in a configuration of grain. Alternatively, each of the green light emitting diodes 45 may be in a configuration of strip or other types. In this embodiment, the green light emitting diodes 45 and the lamps 41 are arrayed alternatively by column. Alternatively, all of the lamps 41 may be surrounded by the green light emitting diodes 45.

FIG. 5 is a diagram of a light emitting diode according to the present invention. The light emitting diode 5 comprises a blue die 51, a reflector cup lead frame 52, two blue die leads 53 and 54, a fluorescent material layer 55, an encapsulant 56, a red die 57 and two red die leads 58 and 59.

The blue die 51 is a Gallium Nitride (GaN) die and is used for generating blue light when being activated. The red die 57 is used for generating red light having a wavelength between 615 nm and 640 nm when being activated. The material of the red die 57 includes but is not limited to Indium Gallium Aluminium Phosphide (InGaAIP). The reflector cup lead frame 52 is used for receiving the blue die 51, the red die 57 and the fluorescent material layer 55. The blue die 51 is electrically coupled to the blue die leads 53 and 54 that are electrically connected to an outer power source, which provides electrical power to the blue die 51. The red die 57 is electrically coupled to the red die leads 58 and 59 that are electrically connected to an outer power source, which provides electrical power to the red die 57. The fluorescent material layer 55 comprises Yttrium Aluminum Garnet (YAG) phosphor and covers the blue die 51 and red die 57. The fluorescent material layer 55 is used for generating yellow light when being activated. The blue die 51, the red die 57 and the fluorescent material layer 55 are encapsulated by the encapsulant 56 that is a transparent epoxy.

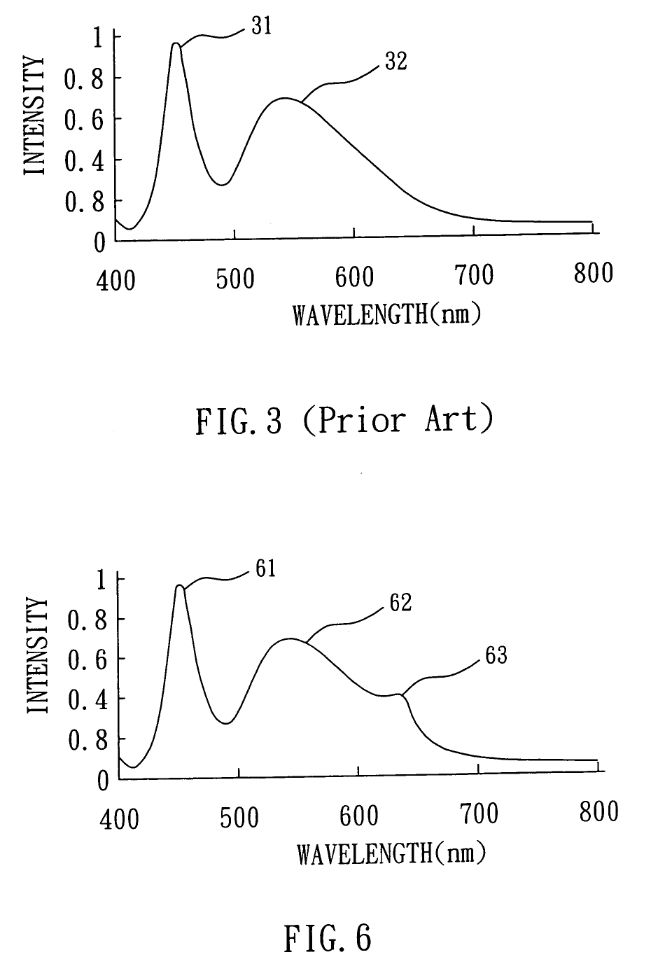

Referring to FIG. 6, a spectral distribution of the white light generated by the light emitting diode 5 of FIG. 5 is shown, wherein the blue die 51 is applied by a direct current of 400 mA, the red die 57 is applied by a direct current of 100 mA. The spectral distribution of the light emitting diode 5 includes three peaks 61, 62 and 63, wherein the peak 61 is primarily caused by the blue die 51 and the peak 62 is primarily caused by the fluorescent material layer 55. Compared with the spectral distribution of FIG. 3, the difference is that the spectral distribution of FIG. 6 has an extra peak 63 which corresponds to the wavelength of 640 nm and is in the red region of the visible spectrum. Therefore, the light emitting diode 5 can compensate red deficiency in the output light of conventional light emitting diode.

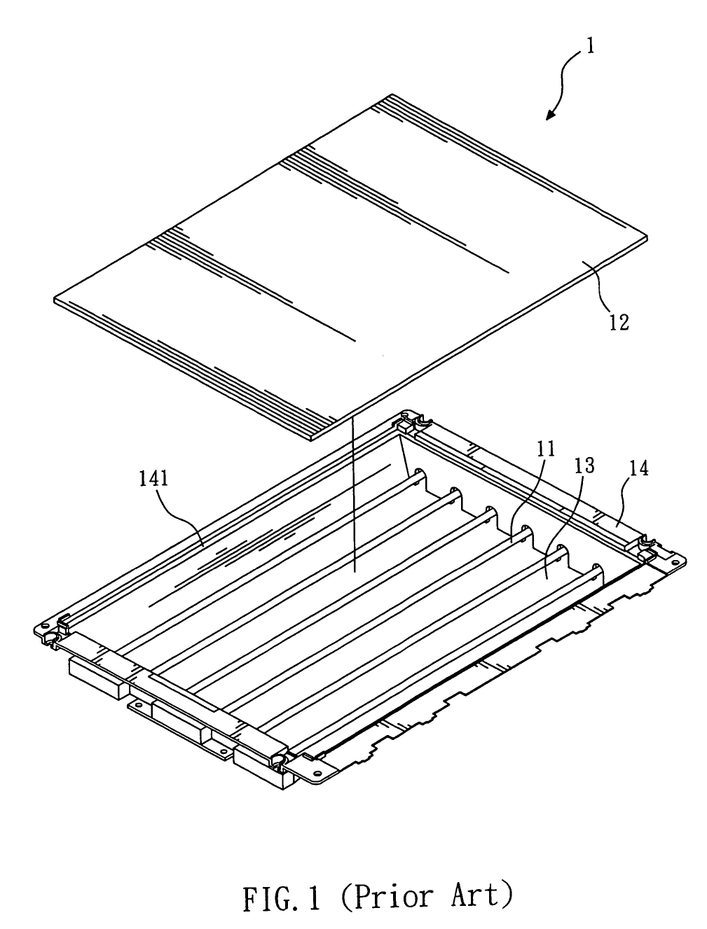

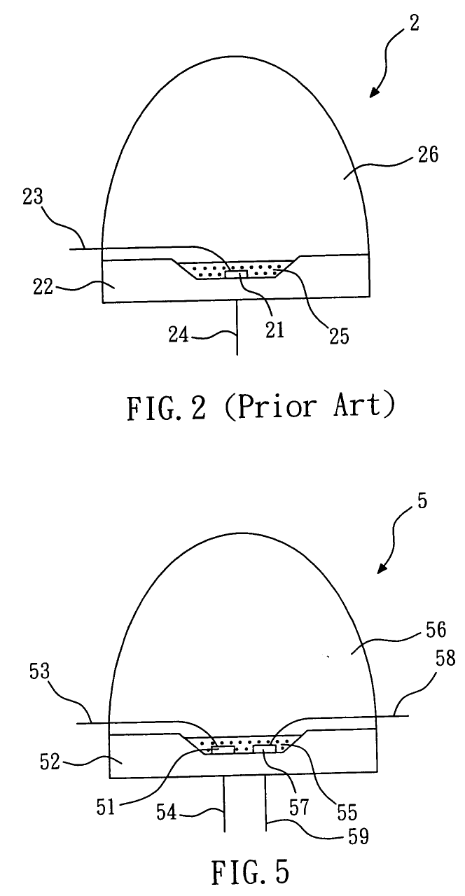

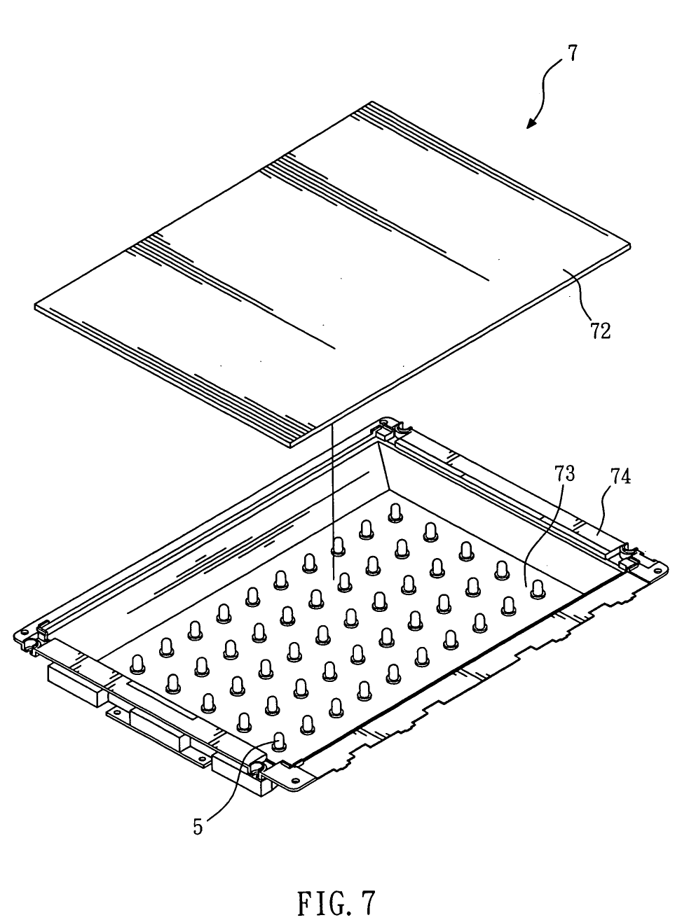

FIG. 7 shows a perspective view of a backlight module according to the present invention, wherein the light emitting diodes 5 of FIG. 5 are adapted in the backlight module 7. The backlight module 7 comprises a plurality of light emitting diodes 5, a diffusion plate 72, a reflective plate 73 and a housing 74. The backlight module 7 is disposed under a liquid crystal plate in a liquid crystal display device (not shown in the figure). The light emitting diodes 5 are same as the light emitting diodes 5 of FIG. 5 and are used for providing light beams. The diffusion plate 72, reflective plate 73 and housing 74 are same as the diffusion plate 12, reflective plate 13 and housing 14 of the conventional light emitting diodes 1 as shown in FIG. 1. Because the light emitting diodes 5 can compensate the red deficiency in the output light, when the backlight module 7 is applied in a liquid crystal display television or a liquid crystal display device, they can increase the color saturation of the liquid crystal display television or the liquid crystal display device.

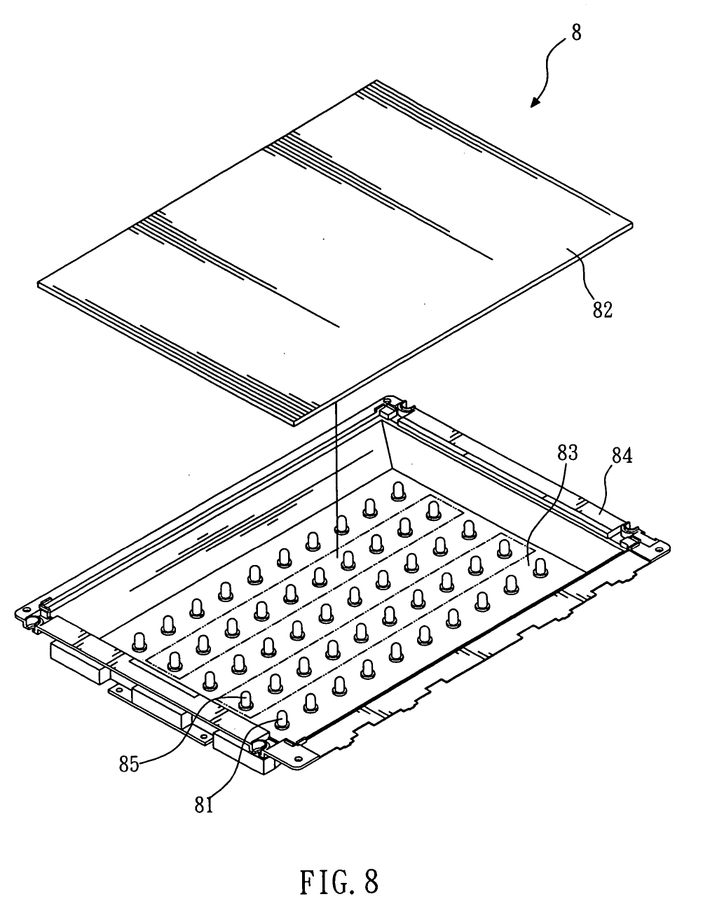

FIG. 8 shows a perspective view of another type of backlight module according to the present invention. The backlight module 8 comprises a plurality of white light emitting diodes 81, a diffusion plate 82, a reflective plate 83, a housing 84 and a plurality of red light emitting diodes 85. The backlight module 8 is disposed under a liquid crystal plate in a liquid crystal display device (not shown in the figure). The white light emitting diodes 81 are conventional white light emitting diodes and are used for providing main light beams. The red light emitting diodes 85 are conventional red light emitting diodes and are used for compensating the red deficiency in the output white light of the conventional white light emitting diodes 81. The diffusion plate 82, reflective plate 83 and housing 84 are same as the diffusion plate 12, reflective plate 13 and housing 14 of the conventional light emitting diodes 1 as shown in FIG. 1. In this embodiment, the red light emitting diodes 85 are added for compensating the red deficiency in the output light; therefore, when the backlight module 8 is applied in a liquid crystal display television or a liquid crystal display device, they can increase the color saturation of the liquid crystal display television or the liquid crystal display device. In this embodiment, the red light emitting diodes 85 and the white light emitting diodes 81 are arrayed alternatively by column. However, in other application, all of the white light emitting diodes 81 are surrounded by the red light emitting diodes 85, or they are arrayed alternatively.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

1-4. (canceled)

5. A backlight module comprising:
a housing;
a light source disposed in the housing;
a reflective plate disposed under the light source and used for reflecting light beams generated by the light source; and
a diffusion plate disposed above the light source and used for diffusing the light beams generated by the light source and reflected by the reflective plate; characterized in that
the light source comprises a plurality of lamps and a plurality of green light emitting diodes.

6. The backlight module according to claim 5, wherein the lamps are cold cathode fluorescent lamps.

7. The backlight module according to claim 5, wherein the lamps and the green light emitting diodes are arrayed alternatively.

8. The backlight module according to claim 5, wherein each of the green light emitting diodes is in a configuration of strip.

9. The backlight module according to claim 5, wherein all of the lamps are surrounded by the green light emitting diodes.

10. A liquid crystal display comprising the backlight module of claim 5.

11. A liquid crystal display television comprising the backlight module of claim 5.

12. A backlight module comprising:
a housing;
a light source disposed in the housing;
a reflective plate disposed under the light source and used for reflecting light beams generated by the light source; and
a diffusion plate disposed above the light source and used for diffusing the light beams generated by the light source and reflected by the reflective plate; characterized in that
the light source comprises a plurality of white light emitting diodes and a plurality of red light emitting diodes.

13. The backlight module according to claim 12, wherein the white light emitting diodes and the red light emitting diodes are arrayed alternatively.

14. The backlight module according to claim 12, wherein all of the white light emitting diodes are surrounded by the red light emitting diodes.

15. A liquid crystal display comprising the backlight module of claim 12.

16. A liquid crystal display television comprising the backlight module of claim 12.
